(19) United States
(12) Patent Application Publication
(10) Pub. No.: US 2026/0089932 A1
(43) Pub. Date: Mar. 26, 2026

(54) SEMICONDUCTOR MEMORY DEVICE

(71) Applicant: SAMSUNG ELECTRONICS CO., LTD., Suwon-si (KR)

(72) Inventors: Sun Jung Lee, Suwon-si (KR); Sang Hyeok Yu, Suwon-si (KR); Seung Jin Jeong, Suwon-si (KR); Do Sun Lee, Suwon-si (KR)

(73) Assignee: SAMSUNG ELECTRONICS CO., LTD., Suwon-si (KR)

(21) Appl. No.: 19/242,172

(22) Filed: Jun. 18, 2025

(30) Foreign Application Priority Data
Sep. 20, 2024 (KR) 10-2024-0127055
Oct. 4, 2024 (KR) 10-2024-0134776

(51) Int. Cl. H10B 12/00; H10D 62/17; H10D 62/80

(52) U.S. Cl. CPC H10B 12/488; H10B 12/315; H10B 12/482; H10D 62/292; H10D 62/875

(57) ABSTRACT

A semiconductor memory device includes a bitline extending in a first direction; a first channel pattern on an upper surface of the bitline; a second channel pattern on the upper surface of the bitline; a first wordline extending in a second direction; a second wordline extending in the second direction; a first capacitor and a second capacitor connected to the first channel pattern and the second channel pattern, respectively; a first gate insulating pattern; a second gate insulating pattern ; a first ruthenium structure between the first channel pattern and the first capacitor; and a second ruthenium structure between the second channel pattern and the second capacitor, wherein an uppermost surface of the first gate insulating pattern is provided without the first ruthenium structure provided thereon, and an uppermost surface of the second gate insulating pattern is provided without the second ruthenium structure provided thereon.

### CROSS-REFERENCE TO RELATED APPLICATIONS

This application claims priority to Korean Patent Application No. 10-2024-0127055, filed on Sep. 20, 2024, and Korean Patent Application No. 10-2024-0134776, filed on Oct. 4, 2024, in the Korean Intellectual Property Office, the disclosures of which are incorporated by reference herein in their entireties.

### BACKGROUND

### 1. Field

The present disclosure relates to a semiconductor memory device.

### 2. Description of Related Art

To meet consumer demands for excellent performance and low cost, increasing the integration density of semiconductor memory devices is necessary. Since the integration density of semiconductor memory devices is a crucial factor in determining the product price, a particularly higher integration density is required.

The integration density of two-dimensional (2D) or planar semiconductor memory devices is primarily determined by the area occupied by unit memory cells and is, thus, greatly influenced by the level of fine patterning technology. However, since ultra-high-cost equipment is needed for miniaturizing patterns, the integration density of 2D semiconductor memory devices, although increasing, remains limited. Accordingly, semiconductor memory devices including vertical channel transistors (VCTs), where the channels extend vertically, have been proposed.

### SUMMARY

One or more example embodiments provide a semiconductor memory device capable of improving device performance and reliability.

According to an aspect of the disclosure, a semiconductor memory device includes: a substrate; a bitline extending in a first direction on the substrate; a first channel pattern on an upper surface of the bitline; a second channel pattern on the upper surface of the bitline and spaced apart from the first channel pattern in the first direction, each of the first channel pattern and the second channel pattern including a metal oxide; a first wordline between the first channel pattern and the second channel pattern and extending in a second direction; a second wordline between the first channel pattern and the second channel pattern, extending in the second direction, and spaced apart from the first wordline in the first direction; a first capacitor on the first channel pattern and connected to the first channel pattern; a second capacitor on the second channel pattern and connected to the second channel pattern; a first gate insulating pattern between the first channel pattern and the first wordline and extending along a profile of the first channel pattern; a second gate insulating pattern between the second channel pattern and the second wordline and extending along a profile of the second channel pattern; a first ruthenium structure between the first channel pattern and the first capacitor; and a second ruthenium structure between the second channel pattern and the second capacitor, wherein an uppermost surface of the first gate insulating pattern is provided without the first ruthenium structure thereon, and an uppermost surface of the second gate insulating pattern is provided without the second ruthenium structure thereon.

According to an aspect of the disclosure, a semiconductor memory device includes: a substrate; a bitline extending in a first direction on the substrate; a channel pattern on an upper surface of the bitline and including a metal oxide; a wordline extending in a second direction on the channel pattern; a gate insulating pattern between the channel pattern and the wordline; a landing pad on the channel pattern; and a ruthenium structure between the channel pattern and the landing pad and connecting the channel pattern and the landing pad, wherein the channel pattern includes a horizontal part contacting the bitline and a vertical part extending in a third direction from the horizontal part, and an uppermost surface of the gate insulating pattern is provided without the ruthenium structure thereon.

According to an aspect of the disclosure, a semiconductor memory device includes: a substrate; a peripheral gate structure on the substrate; a bitline extending in a first direction on the peripheral gate structure; a channel pattern on an upper surface of the bitline and including a metal oxide; a wordline on the channel pattern and extending in a second direction; a gate insulating pattern between the channel pattern and the wordline; a landing pad on the channel pattern and connected to the channel pattern; a ruthenium structure between the channel pattern and the landing pad; and a data storage pattern on the landing pad, wherein the channel pattern includes a horizontal part contacting the bitline and a vertical part extending in a third direction from the horizontal part, and an uppermost surface of the gate insulating pattern is provided without the ruthenium structure thereon.

It should be noted that the effects of the present disclosure are not limited to those described above, and other effects of the present disclosure will be apparent from the following description.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram for explaining a semiconductor memory device according to one or more example embodiments;

FIG. 2 is a cross-sectional view taken along lines A-A and B-B of FIG. 1;

FIG. 3 is a cross-sectional view taken along lines C-C and D-D of FIG. 1;

FIG. 4 is an enlarged cross-sectional view of part P of FIG. 2 according to one or more example embodiments;

FIG. 5 is an enlarged view of part P of FIG. 2 according to one or more example embodiments;

FIG. 6 is an enlarged view of part P of FIG. 2 according to one or more example embodiments;

FIG. 7 is an enlarged view of part P of FIG. 2 according to one or more example embodiments;

FIG. 8 is a layout diagram for explaining a semiconductor memory device according to one or more example embodiments;

FIG. 9 is a cross-sectional view taken along lines E-E and F-F of FIG. 8;

FIG. 10 is a cross-sectional view taken along lines G-G and H-H of FIG. 8;

FIG. 11 is an enlarged view of part Q of FIG. 9 according to one or more example embodiments;

FIGS. 12, 13, 14 and 15 are diagrams for explaining semiconductor memory devices according to one or more example embodiments; and

FIGS. 16, 17, 18, 19, 20, 21, 22, 23, 24, 25, 26, 27, 28, 29, 30, 31, 32, 33, 34, 35, 36, 37, 38, 39 and 40 are diagrams illustrating a method for manufacturing a semiconductor memory device according to one or more example embodiments.

### DETAILED DESCRIPTION

Hereinafter, one or more example embodiments will be described in detail with reference to the accompanying drawings. The same reference numerals are used for the same components in the drawings, and duplicate descriptions thereof are omitted.

In this disclosure, although terms such as “first,” “second,” etc. are used to describe various elements or components, these elements or components are not limited by these terms. These terms are merely used to distinguish one element or component from another. Therefore, a first element or component mentioned below may be a second element or component within the technical spirit of one or more example embodiments.

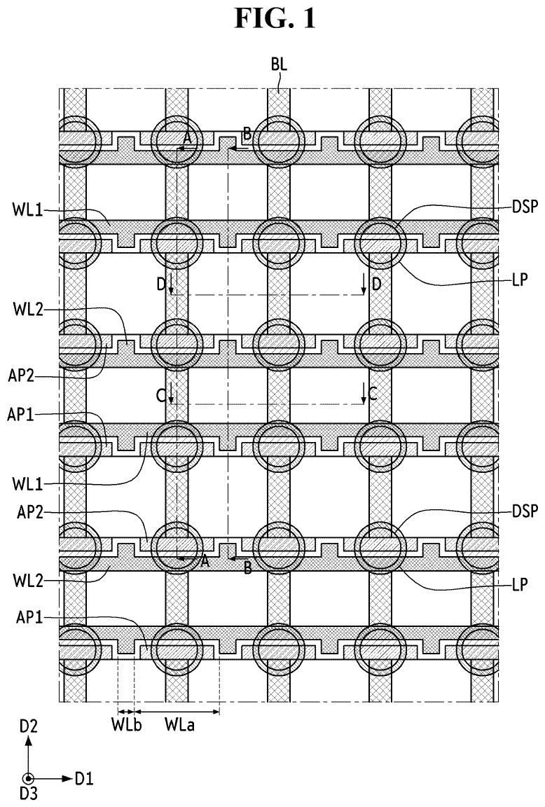

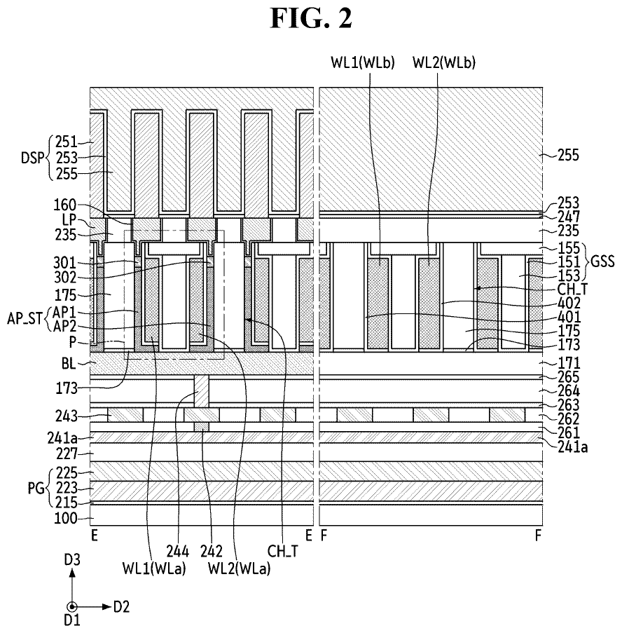

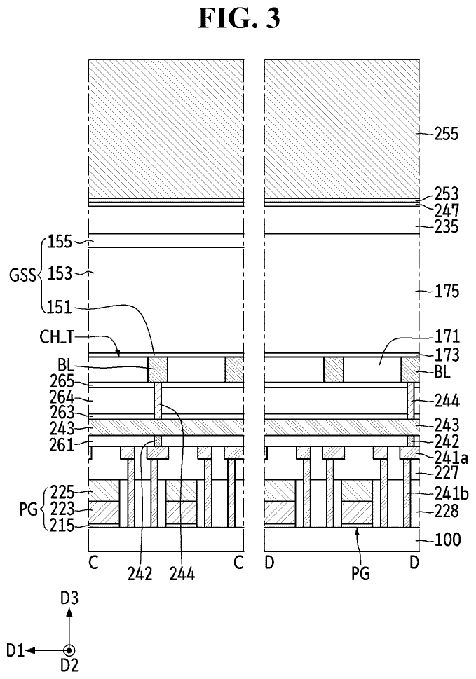

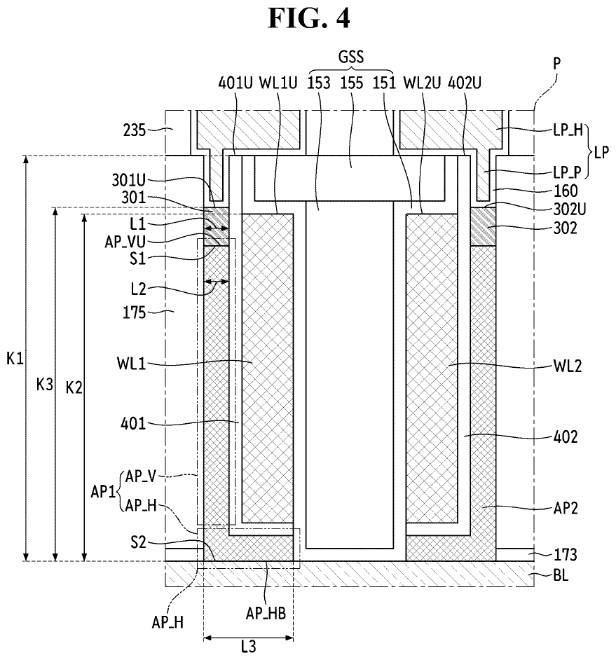

FIG. 1 is a layout diagram for explaining a semiconductor memory device according to one or more example embodiments. FIG. 2 is a cross-sectional view taken along lines A-A and B-B of FIG. 1. FIG. 3 is a cross-sectional view taken along lines C-C and D-D of FIG. 1. FIG. 4 is an enlarged cross-sectional view of part P of FIG. 2 according to one or more example embodiments.

The semiconductor memory device according to one or more example embodiments may include memory cells containing vertical channel transistors (VCTs).

Referring to FIGS. 1, 2, 3 and 4, the semiconductor memory device according to one or more example embodiments may include a peripheral gate structure PG, bitlines BL, protruding insulating patterns 175, channel structures AP_ST, first and second ruthenium structures 301 and 302, wordlines WL1 and WL2, and data storage parts DSP.

The substrate 100 may be a silicon (Si) substrate, or may include other materials, such as silicon-germanium (SiGe), indium antimonide, a lead telluride compound, indium arsenide, indium phosphide, gallium arsenide, or gallium antimonide, but one or more example embodiments are not limited thereto.

The peripheral gate structure PG may be disposed on the substrate 100. The substrate 100 may include a cell array region and a peripheral circuit region. The peripheral gate structure PG may be arranged across both the cell array region and the peripheral circuit region. In other words, some portions of the peripheral gate structure PG may be disposed in the cell array region of the substrate 100, while other portions of the peripheral gate structure PG may be disposed in the peripheral circuit region of the substrate 100.

The peripheral gate structure PG may be included in sensing transistors, transfer transistors, driving transistors, etc. The types of transistors disposed in the cell array region and the peripheral circuit region may vary depending on the design layout of the semiconductor memory device according to one or more example embodiments.

The peripheral gate structure PG may include a peripheral gate insulating film 215, peripheral lower conductive patterns 223, and peripheral upper conductive patterns 225. The peripheral gate insulating film 215 may include a silicon oxide film, a silicon oxynitride film, a high-k dielectric film with a greater dielectric constant than a silicon oxide film, or a combination thereof. The high-k dielectric film may include, for example, at least one of a metal oxide, a metal oxynitride, a metal silicon oxide, or a metal silicon oxynitride, but embodiments are not limited thereto.

The peripheral lower conductive patterns 223 and the peripheral upper conductive patterns 225 may each include a conductive material. For example, the peripheral lower conductive patterns 223 and the peripheral upper conductive patterns 225 may each include at least one of a doped semiconductor material, a conductive metal nitride, a conductive metal silicon nitride, a metal carbonitride, a conductive metal silicide, a conductive metal oxide, a two-dimensional (2D) material, a metal, or a metal alloy. The peripheral gate structure PG is illustrated as including multiple conductive patterns, but embodiments are not limited thereto.

In the semiconductor memory device according to one or more example embodiments, the 2D material may be a metallic material and/or a semiconductor material. The 2D material may include a 2D allotrope or a 2D compound. For example, the 2D material may include, for example, at least one of graphene, molybdenum disulfide (MoS₂), molybdenum diselenide (MoSe₂), tungsten diselenide (WSe₂), or tungsten disulfide (WS₂), but embodiments are not limited thereto. In other words, the above-mentioned 2D materials are listed only as examples, and the 2D material that may be included in the semiconductor memory device according to one or more example embodiments is not particularly limited.

A first peripheral lower insulating film 227 and a second peripheral lower insulating film 228 may be disposed on the substrate 100. Each of the first and second peripheral lower insulating films 227 and 228 may include an insulating material.

First peripheral wiring lines 241a and peripheral contact plugs 241b may be disposed within the first and second peripheral lower insulating films 227 and 228. The first peripheral wiring lines 241a and the peripheral contact plugs 241b are illustrated as different films, but embodiments are not limited thereto. The boundaries between the first peripheral wiring lines 241a and the peripheral contact plugs 241b may not be distinguishable. The first peripheral wiring lines 241a and the peripheral contact plugs 241b may each include a conductive material.

A first peripheral upper insulating film 261 and a second peripheral upper insulating film 262 may be disposed on the first peripheral wiring lines 241a and the peripheral contact plugs 241b. Each of the first and second peripheral upper insulating films 261 and 262 may include an insulating material.

Second peripheral wiring lines 243 and peripheral via plugs 242 may be disposed on the first peripheral wiring lines 241a. The peripheral via plugs 242 may be disposed within the first peripheral upper insulating film 261. The second peripheral wiring lines 243 may be disposed within the second peripheral upper insulating film 262.

The second peripheral wiring lines 243 and the peripheral via plugs 242 may be connected to the first peripheral wiring lines 241a. The peripheral via plugs 242 may connect the first peripheral wiring lines 241a and the second peripheral wiring lines 243. The second peripheral wiring lines 243 and the peripheral via plugs 242 each include a conductive material. The second peripheral wiring lines 243 and the peripheral via plugs 242 are illustrated as different films, but embodiments are not limited thereto. The boundaries between the second peripheral wiring lines 243 and the peripheral via plugs 242 may not be distinguishable.

A third peripheral upper insulating film 263, a fourth peripheral upper insulating film 264, and a fifth peripheral upper insulating film 265 may be sequentially disposed on the second peripheral wiring lines 243. Each of the third, fourth, and fifth peripheral upper insulating films 263, 264, and 265, may include an insulating material.

The fourth peripheral upper insulating film 264 may include a different insulating material from the third and fifth peripheral upper insulating films 263 and 265. For example, the fourth peripheral upper insulating film 264 may be formed of an oxide-based insulating material, but embodiments are not limited thereto, and the third and fifth peripheral upper insulating films 263 and 265 may be formed of a nitride-based insulating material, but embodiments are not limited thereto.

Cell connection plugs 244 may be disposed within the third, fourth, and fifth peripheral upper insulating films 263, 264, and 265. The cell connection plugs 244 may be connected to the second peripheral wiring lines 243. The cell connection plugs 244 include a conductive material. Alternatively, the cell connection plugs 244 may be disposed in a single-film peripheral upper insulating film.

The bitlines BL may be disposed on the peripheral gate structure PG. Specifically, the bitlines BL may be disposed on the fifth peripheral upper insulating film 265. For example, the bitlines BL may be in contact with the fifth peripheral upper insulating film 265.

The bitlines BL may extend in a second direction D2. Adjacent bitlines BL may be spaced apart in a first direction D1. Each of the bitlines BL may include long sidewalls extending in the second direction D2 and short sidewalls extending in the first direction D1.

The bitlines BL may extend from the cell array region to the peripheral circuit region. The ends of each of the bitlines BL may be disposed on the peripheral circuit region of the substrate 100.

The bitlines BL may be disposed on the cell connection plugs 244. The bitlines BL may be connected to the cell connection plug 244. The bitlines BL may include, for example, at least one of a doped semiconductor material, a conductive metal nitride, a conductive metal silicon nitride, a metal carbonitride, a conductive metal silicide, a conductive metal oxide, a two-dimensional material, a metal, or a metal alloy. The bitlines BL are illustrated as single films, but embodiments are not limited thereto.

A cell lower insulating film 171 may be disposed on the fifth peripheral upper insulating film 265. The cell lower insulating film 171 may be disposed between bitlines BL spaced apart in the first direction D1. The cell lower insulating film 171 may include an insulating material.

The protruding insulating patterns 175 may be disposed on the bitlines BL and the cell lower insulating film 171. A cell lower etch stop film 173 may be disposed between the protruding insulating patterns 175 and the cell lower insulating film 171. The protruding insulating patterns 175 and the cell lower etch stop film 173 may each include an insulating material. The cell lower etch stop film 173 may include a material with an etch selectivity with respect to the protruding insulating patterns 175. For example, the protruding insulating patterns 175 may be formed of an oxide-based insulating material, but embodiments are not limited thereto. Alternatively, the cell lower etch stop film 173 may not be disposed between the protruding insulating patterns 175 and the cell lower insulating film 171.

The protruding insulating patterns 175 may include multiple channel trenches CH_T. The channel trenches CH_T may extend in the first direction D1. Adjacent channel trenches CH_T may be spaced apart in the second direction D2.

The channel trenches CH_T may intersect the bitlines BL. One channel trench CH_T may expose multiple adjacent bitlines BL in the first direction D1. The lower surfaces of the channel trenches CH_T may be defined by the bitlines BL and the cell lower insulating film 171. The sidewalls of the channel trenches CH_T may be defined by the protruding insulating patterns 175 and the cell lower etch stop film 173. If the cell lower etch stop film 173 is omitted, the sidewalls of the channel trenches CH_T may be defined by the protruding insulating patterns 175.

The channel structures AP_ST may include first channel patterns AP1 and second channel patterns AP2. The first channel patterns AP1 and the second channel patterns AP2 may be disposed on the bitlines BL. Pairs of first and second channel patterns AP1 and AP2 may be connected to one bitline BL. The pairs of first and second channel patterns AP1 and AP2 disposed on one bitline BL may be spaced apart in the second direction D2.

The channel structures AP_ST may be disposed within the channel trenches CH_T extending in the first direction D1. Pairs of first and second channel patterns AP1 and AP2 may be disposed within one channel trench CH_T. The pairs of first and second channel patterns AP1 and AP2 disposed within one channel trench CH_T may be spaced apart in the first direction D1. For example, the channel structures AP_ST may be arranged two-dimensionally along the first and second directions D1 and D2, which intersect each other.

Gate separation patterns GSS, which will be described later, may be disposed between the first channel patterns AP1 and the second channel patterns AP2. In other words, the first channel patterns AP1 and the second channel patterns AP2 may be disposed to face each other with gate separation films 153, which will be described later, in between. The first channel patterns AP1 and the second channel patterns AP2 may have a symmetrical shape, but embodiments are not limited thereto. In one or more example embodiments, the first channel patterns AP1 and the second channel patterns AP2 may have different shapes. The shape of the first channel patterns AP1 alone will hereinafter be described under the assumption that the first channel pattern AP1 and the second channel pattern AP2 have the same shape, as illustrated.

The first channel patterns AP1 may include horizontal parts AP_H and vertical parts AP_V, which are connected to the horizontal parts AP_H. For example, the first channel patterns AP1 may include an L-shaped structure where the horizontal parts AP_H and the vertical parts AP_V are connected. The horizontal parts AP_H may be in direct contact with the bitlines BL. For example, lower surfaces AP_HB of the horizontal parts AP_H may be in direct contact with the bitlines BL. The vertical parts AP_V may extend from the horizontal parts AP_H in a third direction D3.

The first channel patterns AP1 may include first surfaces S1 and second surfaces S2, which are opposite to the first surfaces S1. The first surfaces S1 may refer to upper surfaces AP_VU of the vertical parts AP_V of the first channel patterns AP1. The second surfaces S2 may correspond to the lower surfaces AP_HB of the horizontal parts AP_H of the first channel pattern AP1. The first surfaces S1 may be in direct contact with the first ruthenium structure 301. The second surfaces S2 may be in direct contact with the bitlines BL.

The channel structures AP_ST may include an oxide semiconductor material. In the semiconductor memory device according to one or more example embodiments, the first channel patterns AP1 and the second channel patterns AP2 may include, for example, at least one of indium gallium zinc oxide (IGZO), doped indium zinc oxide (IZO), indium oxide (InO), zinc oxide (ZnO), gallium oxide (GaO), tin oxide (SnO), aluminum zinc oxide (AZO), and indium tin oxide (ITO). In the case of the doped IZO, the doped impurities may include, for example, at least one of magnesium (Mg), strontium (Sr), barium (Ba), scandium (Sc), yttrium (Y), lanthanum (La), titanium (Ti), zirconium (Zr), hafnium (Hf), aluminum (Al), tin (Sn), or tantalum (Ta).

The first ruthenium structure 301 may be disposed on the upper surfaces of the first channel patterns AP1. For example, the first ruthenium structure 301 may be disposed on the first surfaces S1 of the vertical parts AP_V of the first channel patterns AP1. A length L1 of the first ruthenium structure 301 in the second direction D2 may be the same as a length L2 of the vertical parts AP_V in the second direction D2, but one or more example embodiments are not limited thereto. Alternatively, in one or more example embodiments, the length L1 of the first ruthenium structure 301 in the second direction D2 may be greater than the length L2 of the vertical part AP_V in the second direction D2. The first ruthenium structure 301 may include ruthenium (Ru).

The second ruthenium structure 302 may be disposed on the upper surfaces of the second channel patterns AP2. The positional relationship between the second ruthenium structure 302 and the second channel patterns AP2 may be the same as the positional relationship between the first ruthenium structure 301 and the first channel patterns AP1. The second ruthenium structure 302 may include Ru.

First wordlines WL1 and second wordlines WL2 may be disposed on the channel structures AP_ST. The first wordlines WL1 and the second wordlines WL2 may be disposed within the channel trenches CH_T.

The first wordlines WL1 and the second wordlines WL2 may extend in the first direction D1. The first wordlines WL1 and the second wordlines WL2 may be alternately arranged in the second direction D2. The first wordlines WL1 may be spaced apart from the second wordlines WL2 in the second direction D2.

The first wordlines WL1 and the second wordlines WL2 may be spaced apart from the bitlines BL in the third direction D3. The first wordlines WL1 and the second wordlines WL2 may intersect the bitlines BL.

The first wordlines WL1 and the second wordlines WL2 may be disposed on the horizontal parts AP_H of the channel patterns (AP1 and AP2). The first wordlines WL1 may be disposed on the first channel patterns AP1. The second wordlines WL2 may be disposed on the second channel patterns AP2. The first wordlines WL1 and the second wordlines WL2 may be disposed between the first channel patterns AP1 and the second channel patterns AP2. The first channel patterns AP1 are more adjacent to the first wordlines WL1 than to the second wordlines WL2. The second channel patterns AP2 are more adjacent to the second wordlines WL2 than to the first wordlines WL1.

The first wordlines WL1 and the second wordlines WL2 may each have a width in the second direction D2. The width of the first wordlines WL1 in the area overlapping with the channel structures AP_ST in the third direction D3 may differ from the width of the first wordlines WL1 in the area not overlapping with the channel structures AP_ST. Similarly, the width of the second wordlines WL2 in the area overlapping with the channel structures AP_ST in the third direction D3 may differ from the width of the second wordlines WL2 in the area not overlapping with the channel structures AP_ST.

For example, the first wordline WL1 and the second wordline WL2 may each include first portions WLa and a second portions WLb. The width of the first portions WLa of the wordlines (WL1 and WL2) in the second direction D2 may be smaller than the width of the second portions WLb of the wordlines (WL1 and WL2) in the second direction D2. For example, the first portions WLa of the wordlines (WL1 and WL2) may be disposed on the channel structures CH_ST. The first portions WLa of the wordlines (WL1 and WL2) may be disposed on the channel patterns (AP1 and AP2).

The first wordlines WL1 and the second wordlines WL2 may each include first portions WLa and second portions WLb arranged alternately along the first direction D1. Each of the channel structures AP_ST may be disposed between adjacent second portions WLb in the first direction D1. In each of the first wordlines WL1, each of the first active patterns AP1 may be disposed between the adjacent second portions WLb in the first direction D1. In each of the second wordlines WL2, each of the second active patterns AP2 may be disposed between the adjacent second portions WLb adjacent in the first direction D1.

The wordlines (WL1 and WL2) may include a conductive material. For example, the wordlines (WL1 and WL2) may include at least one of doped polysilicon, a conductive metal nitride, a conductive metal silicon nitride, a metal carbonitride, a conductive metal silicide, a conductive metal oxide, a 2D material, a metal, or a metal alloy.

First gate insulating patterns 401 may be disposed between the first wordlines WL1 and the channel structures AP_ST. Second gate insulating patterns 402 may be disposed between the second wordlines WL2 and the channel structures AP_ST. The first gate insulating patterns 401 may be disposed between the first wordlines WL1 and the first channel patterns AP1. The second gate insulating patterns 402 may be disposed between the second wordlines WL2 and the second channel patterns AP2. The first gate insulating patterns 401 and the second gate insulating patterns 402 may extend parallel to the first wordlines WL1 and the second wordlines WL2, respectively, in the first direction D1.

The first gate insulating patterns 401 and the second gate insulating patterns 402 may each include a silicon oxide film, a silicon oxynitride film, a high-k dielectric film with a higher dielectric constant than a silicon oxide film, or a combination thereof.

Portions of the first gate insulating patterns 401 may protrude in the third direction D3 beyond upper surfaces WL1U of the first wordlines WL1. Portions of the second gate insulating patterns 402 may protrude in the third direction D3 beyond upper surfaces WL2U of the second wordlines WL2. Portions of the first gate insulating patterns 401 may protrude in the third direction D3 beyond the first surfaces S1 of the vertical parts AP_V of the first channel patterns AP1. Upper surfaces 402U of the second gate insulating patterns 402 may be disposed on the same plane as upper surfaces 401U of the first gate insulating patterns 401.

A height K2 in the third direction D3 from the lower surfaces AP_HB of the horizontal parts AP_H of the first channel patterns AP1 to the upper surfaces WL1U of the first wordlines WL1 may be less than a height K3 in the third direction D3 from the lower surfaces AP_HB of the horizontal parts AP_H of the first channel patterns AP1 to an upper surface 301U of the first ruthenium structure 301. In other words, the upper surface 301U of the first ruthenium structure 301 may be disposed above the upper surfaces WL1U of the first wordlines WL1.

The height K2 in the third direction D3 from the lower surfaces AP_HB of the horizontal parts AP_H of the first channel patterns AP1 to the upper surfaces WL1U of the first wordlines WL1 may be less than a height K1 in the third direction D3 from the lower surfaces AP_HB of the horizontal parts AP_H of the first channel patterns AP1 to the upper surfaces 401U of the first gate insulating patterns 401. In other words, the upper surfaces WL1U of the first wordlines WL1 may be disposed below the upper surfaces 401U of the first gate insulating patterns 401.

A height K3 in the third direction D3 from the lower surfaces AP_HB of the horizontal parts AP_H of the first channel patterns AP1 to the upper surface 301U of the first ruthenium structure 301 may be less than the height K1 in the third direction D3 from the lower surfaces AP_HB of the horizontal parts AP_H of the first channel patterns AP1 to the upper surface 401U of the first gate insulating pattern 401. In other words, the upper surface 301U of the first ruthenium structure 301 may be disposed below the upper surfaces 401U of the first gate insulating patterns 401.

The gate separation patterns GSS may be disposed on the bitlines BL and the cell lower insulating film 171. The gate separation patterns GSS may be disposed within the channel trenches CH_T. The gate separation patterns GSS may be disposed on the channel structures AP_ST, the first wordlines WL1, and the second wordlines WL2.

In the semiconductor memory device according to one or more example embodiments, the gate separation patterns GSS may be in contact with the channel structures AP_ST. For example, the gate separation patterns GSS may be in contact with the horizontal parts AP_H of the first channel structures AP_ST. The gate separation patterns GSS may be spaced apart from the bitlines BL in the third direction D3.

The gate separation patterns GSS may be disposed between pairs of first and second wordlines WL1 and WL2 in the second direction D2. The first wordlines WL1 and the second wordlines WL2 may be separated by the gate separation patterns GSS. The gate separation patterns GSS may extend in the first direction D1 between the first wordlines WL1 and the second wordlines WL2.

The first wordlines WL1 may be disposed between the gate separation patterns GSS and the channel structures AP_ST. The second wordlines WL2 may be disposed between the gate separation patterns GSS and the channel structures AP_ST. The first wordlines WL1 may be disposed between the gate separation patterns GSS and the first channel patterns AP1. The second wordlines WL2 may be disposed between the gate separation patterns GSS and the second channel patterns AP2.

The gate separation patterns GSS may include horizontal parts and protrusions. The protrusions of the gate separation patterns GSS may protrude from the horizontal parts of the gate separation patterns GSS toward the bitlines BL in the third direction D3. The protrusions of the gate separation patterns GSS may be closer than the horizontal parts of the gate separation patterns GSS to the bitlines BL. The horizontal parts of the gate separation patterns GSS may be disposed on the upper surfaces WL1U of the first wordlines WL1 and the upper surfaces WL2U of the second wordlines WL2. From a cross-sectional perspective, the gate separation patterns GSS may have a “T” shape.

The gate separation patterns GSS may include a gate separation liner 151, a gate separation filling film 153, and a gate separation capping film 155. The gate separation liner 151 may extend along the upper surfaces WL1U of the first wordlines WL1 and the upper surfaces WL2U of the second wordlines WL2, and along the outer sidewalls of the first wordlines WL1 and second wordlines WL2. The gate separation liner 151 may extend along the first and second gate insulating films 401 and 402, which protrude above the upper surfaces WL1U of the first wordlines WL1 and the upper surfaces WL2U of the second wordlines WL2. The gate separation liner 151 may extend along at least portions of the bitlines BL. The gate separation liner 151 may be in direct contact with the bitlines BL. Alternatively, the gate separation liner 151 may not extend along the first and second gate insulating films 401 and 402, which protrude above the upper surfaces WL1U of the first wordlines WL1 and the upper surfaces WL2U of the second wordlines WL2.

The gate separation filling film 153 may be disposed on the gate separation liner 151. The gate separation capping film 155 may be disposed on the gate separation filling film 153. The gate separation liner 151, the gate separation filling film 153, and the gate separation capping film 155 may each include an insulating material. Alternatively, the gate separation patterns GSS may be single films.

Landing pads LP may be disposed on the channel structures AP_ST. For example, the landing pads LP may be connected to the vertical parts AP_V of the first channel patterns AP1. The landing pads LP may be disposed on the first channel patterns AP1 and the second channel patterns AP2. The landing pads LP may be connected to the first channel patterns AP1 and the second channel patterns AP2. From a planar perspective, the landing pads LP may have various shapes, such as circular, elliptical, rectangular, square, diamond, hexagonal, etc.

The landing pads LP may include horizontal parts LP_H and protrusions LP_P. The horizontal parts LP_H of the landing pads LP may be disposed on the upper surfaces of the protruding insulating patterns 175 and the upper surfaces of the gate separation patterns GSS. The protrusions LP_P of the landing pads LP may protrude from the horizontal parts LP_H toward the bitlines BL in the third direction D3. The landing pads LP may include, for example, tungsten (W).

Relative to the upper surfaces of the bitlines BL, the lowest portions of the landing pads LP may be positioned below the upper surfaces of the gate separation patterns GSS. In other words, the protrusions LP_P of the landing pads LP may be disposed between the protruding insulating patterns 175 and the gate separation patterns GSS.

A landing pad interface film 160 may be disposed between the landing pads LP and the gate separation patterns GSS, between the landing pads LP and the first and second gate insulating films 401 and 402, between the landing pads LP and the protruding insulating patterns 175, between the landing pads LP and the first and second ruthenium structures 301 and 302, and between the landing pads LP and pad separation insulating patterns 235, which will be described later. The landing pad interface films 160 may include, for example, titanium nitride (TiN).

Pad separation insulating patterns 235 may be disposed between the landing pads LP. From a planar perspective, the landing pads LP may be arranged in a matrix form along the first and second directions D1 and D2. The upper surfaces of the landing pads LP may be positioned on the same plane as the upper surfaces of the pad separation insulating patterns 245, but embodiments are not limited thereto.

The landing pads LP may include a conductive material. For example, the landing pads LP may include at least one of doped polysilicon, a conductive metal nitride, a conductive metal silicon nitride, a metal carbonitride, a conductive metal silicide, a conductive metal oxide, a 2D material, a metal, or a metal alloy.

The data storage patterns DSP may be disposed on the landing pads LP. The data storage patterns DSP may be connected to the first channel patterns AP1 and the second channel patterns AP2. As illustrated in FIG. 1, the data storage patterns DSP may be arranged in a matrix form along the first and second directions D1 and D2. The data storage patterns DSP may fully or partially overlap with the landing pads LP in the third direction D3. The data storage patterns DSP may be in contact with the entire upper surfaces or parts of the upper surfaces of the landing pads LP.

For example, the data storage patterns DSP may be capacitors. The first channel patterns AP1 may be connected to first capacitors, and the second channel patterns AP2 may be connected to second capacitors.

The data storage patterns DSP may include a capacitor dielectric film 253 interposed between storage electrodes 251 and a plate electrode 255. In this case, the storage electrodes 251 may be in contact with the landing pads LP. From a planar perspective, the storage electrodes 251 may have various shapes, such as circular, elliptical, rectangular, square, diamond, or hexagonal. The data storage patterns DSP may fully or partially overlap with the landing pads LP. The data storage patterns DSP may be in contact with the entire upper surfaces or parts of the upper surfaces of the landing pads LP. The storage electrodes 251 may penetrate the cell upper etch stop film 247. The cell upper etch stop film 247 may include an insulating material.

Alternatively, the data storage patterns DSP may be variable resistance patterns that can switch between two resistance states based on electrical pulses applied to memory elements. For example, the data storage patterns DSP may include a phase-change material that changes its crystalline state in accordance with the amount of current, a perovskite compound, a transition metal oxide, a magnetic material, a ferromagnetic material, or an antiferromagnetic material.

The first ruthenium structure 301 is disposed between the first channel patterns AP1 and the landing pads LP. The second ruthenium structure 302 is disposed between the second channel patterns AP2 and the landing pads LP. Due to the presence of the first ruthenium structure 301, the first channel patterns AP1 do not directly contact the landing pads LP. Similarly, the second ruthenium structure 302 prevents the second channel patterns AP2 from directly contacting the landing pads LP.

The vertical parts AP_V may be in direct contact with the first ruthenium structure 301. For example, the upper surfaces AP_VU of the vertical parts AP_V may be in direct contact with the first ruthenium structure 301. The length L2 of the vertical parts AP_V in the second direction D2 may be less than a length L3 of the horizontal parts AP_H in the second direction D2.

When the landing pad interface film 160 is in direct contact with the channel patterns (AP1 and AP2), an oxide film may be formed at the interfaces between the landing pad interface film 160 and the channel patterns (AP1 and AP2). In this case, however, the performance and reliability of the semiconductor according to one or more example embodiments may be degraded. Conversely, according to one or more example embodiments, the landing pad interface film 160, which is prone to oxide formation, does not directly contact the channel patterns (AP1 and AP2), thereby suppressing oxide formation at the interfaces of the channel patterns (AP1 and AP2). In other words, the formation of an oxide film at the interfaces between the first and second ruthenium structures 301 and 302 and the channel patterns (AP1 and AP2) is suppressed, improving the performance and reliability of the semiconductor memory device according to one or more example embodiments.

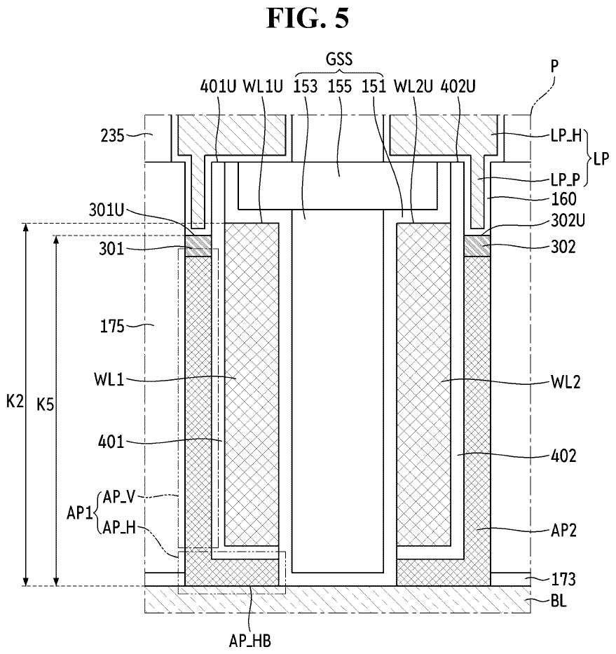

FIG. 5 is an enlarged view of part P of FIG. 2 according to one or more example embodiments. For convenience of explanation, FIG. 5 focuses on the differences from FIGS. 1, 2, 3 and 4. For reference, the following description focuses on a first channel pattern AP1, a first wordline WL1, and a first ruthenium structure 301, but the arrangement of a second channel pattern AP2, a second wordline WL2, and a second ruthenium structure 302 may also be the same as the arrangement of the first channel pattern AP1, the first wordline WL1, and the first ruthenium structure 301.

Referring to FIG. 5, a height K2 in a third direction D3 from a lower surface AP_HB of a horizontal part AP_H of the first channel pattern AP1 to an upper surface WL1U of the first wordline WL1 may be greater than a height K5 in the third direction D3 from the lower surface AP_HB of the horizontal part AP_H of the first channel pattern AP1 to an upper surface 301U of the first ruthenium structure 301. In other words, the upper surface WL1U of the first wordline WL1 may be disposed above the upper surface 301U of the first ruthenium structure 301.

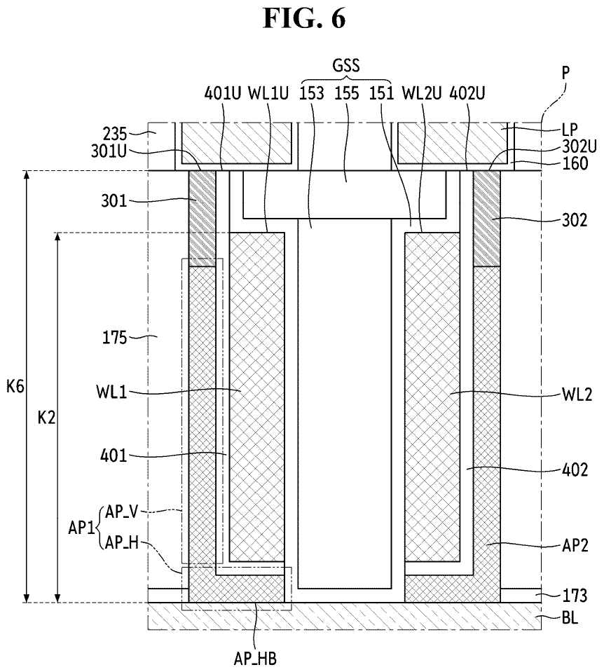

FIG. 6 is an enlarged view of part P of FIG. 2 according to one or more example embodiments. For convenience of explanation, FIG. 6 focuses on the differences from FIGS. 1, 2, 3 and 4. Specifically, the following description focuses on a first channel pattern AP1, a first wordline WL1, and a first ruthenium structure 301, but the arrangement of a second channel pattern AP2, a second wordline WL2, and a second ruthenium structure 302 may also be the same as the arrangement of the first channel pattern AP1, the first wordline WL1, and the first ruthenium structure 301.

Referring to FIG. 6, a height K6 in a third direction D3 from a lower surface AP_HB of a horizontal part AP_H of the first channel pattern AP1 to an upper surface 301U of the first ruthenium structure 301 may be greater than a height K2 in the third direction D3 from a lower surface AP_HB of a horizontal part AP_H of the first channel pattern AP1 to the upper surface WL1U of the first wordline WL1. In other words, the upper surface 301U of the first ruthenium structure 301 may be disposed above the upper surface WL1U of the first wordline WL1. The upper surface 301U of the first ruthenium structure 301 may be disposed on the same plane as an upper surface 401U of a first gate insulating pattern 401.

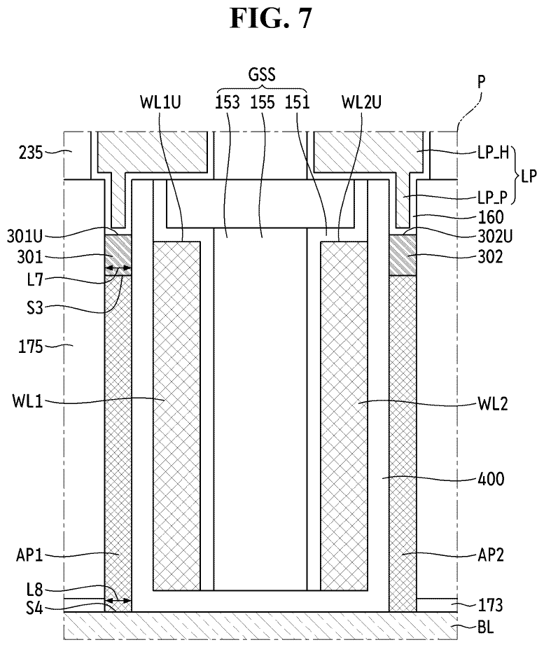

FIG. 7 is an enlarged view of part P of FIG. 2 according to one or more example embodiments. For convenience of explanation, FIG. 7 focuses on the differences from FIGS. 1, 2, 3 and 4. Specifically, the following description focuses on a first channel pattern AP1, a first wordline WL1, and a first ruthenium structure 301, but the arrangement of a second channel pattern AP2, a second wordline WL2, and a second ruthenium structure 302 may also be the same as the arrangement of the first channel pattern AP1, the first wordline WL1, and the first ruthenium structure 301.

Referring to FIG. 7, the first channel pattern AP1 may include a first surface S3 and a second surface S4, which are opposite each other. The first surface S3 may be in direct contact with the first ruthenium structure 301. The second surface S4 may be in direct contact with a bitline BL. The first channel pattern AP1 may have a uniform width. For example, the width of the first surface S3 in a second direction D2 and the width of the second surface S4 in the second direction D2 may be the same.

At least a portion of a gate insulating pattern 400 may extend along the profile of a portion of the bitline BL. The gate insulating pattern 400 may be in direct contact with the bitline BL. The gate insulating pattern 400 may extend along the profiles of the first and second channel patterns AP1 and AP2. From a cross-sectional perspective, the gate insulating pattern 400 may have a “U” shape. A width L7 of the first ruthenium structure 301 in the second direction D2 may be the same as a width L8 of the first channel pattern AP1 in the second direction D2.

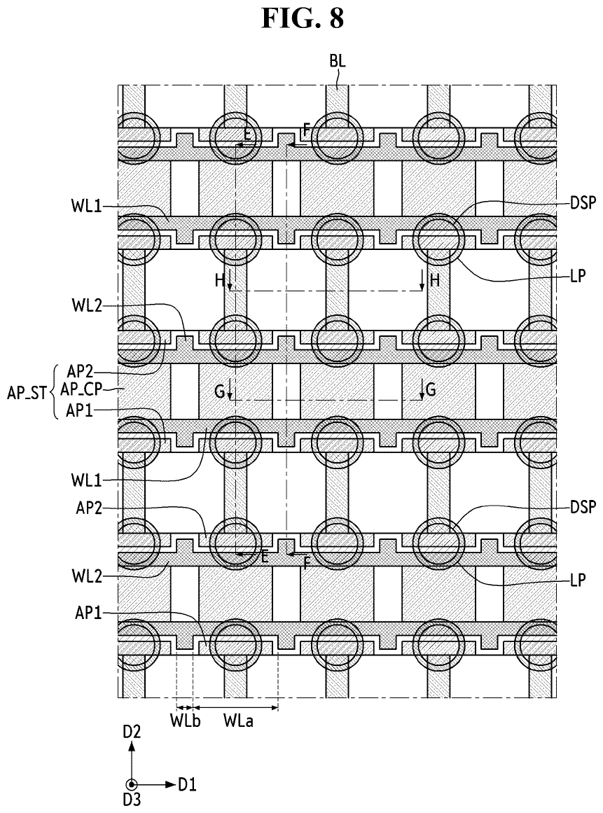

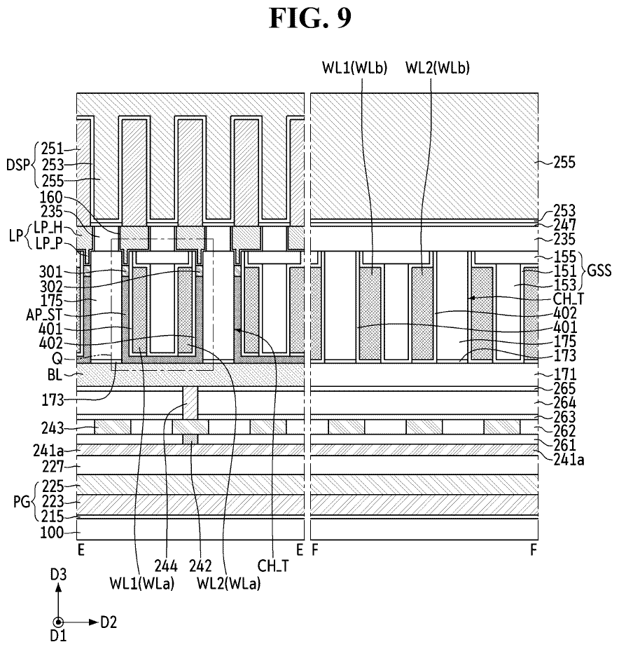

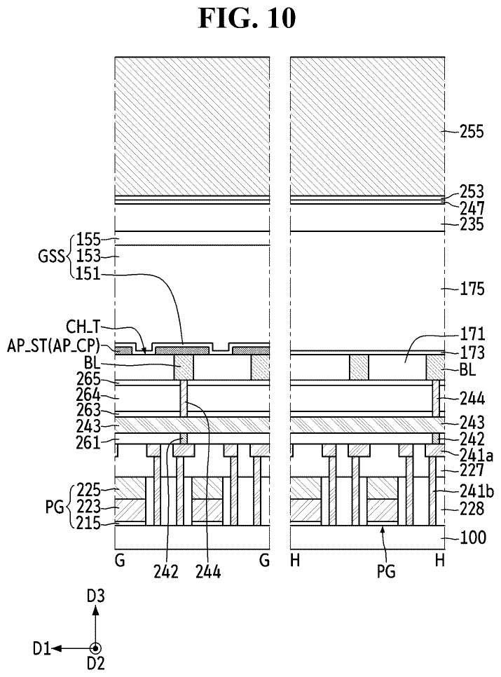

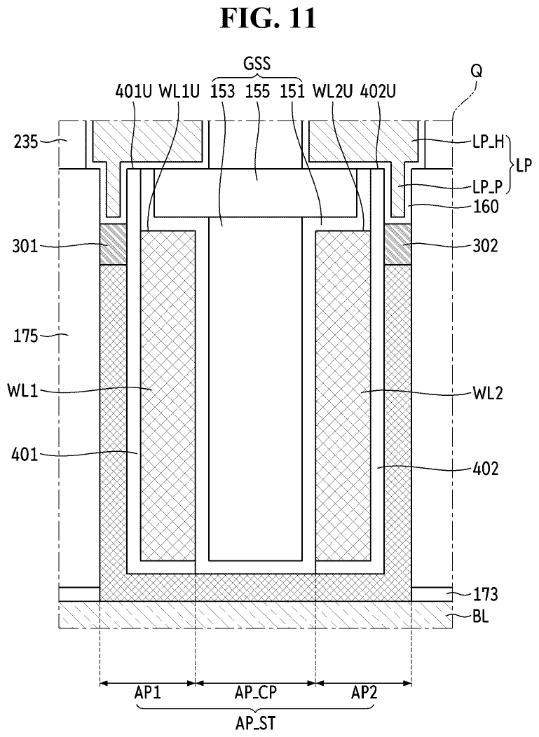

FIG. 8 is a layout diagram for explaining a semiconductor memory device according to one or more example embodiments. FIG. 9 is a cross-sectional view taken along lines E-E and F-F of FIG. 8. FIG. 10 is a cross-sectional view taken along lines G-G and H-H of FIG. 8. FIG. 11 is an enlarged view of part Q of FIG. 9 according to one or more example embodiments. For convenience of explanation, FIG. 8. 9. 10 and 11 focus on the differences from FIGS. 1, 2, 3 and 4.

Referring to FIG. 8, 9, 10 and 11, channel structures AP_ST may include first channel patterns AP1, second channel patterns AP2, and connecting channel patterns AP_CP. The connecting channel patterns AP_CP may connect the first channel patterns AP1 and the second channel patterns AP2. The first channel patterns AP1 and the second channel patterns AP2 may be spaced apart in a second direction D2.

The first channel patterns AP1, the second channel patterns AP2, and the connecting channel patterns AP_CP may be disposed on bitlines BL. The first channel patterns AP1 and the second channel patterns AP2 may be connected to the bitlines BL. The first channel patterns AP1 and the second channel patterns AP2 may be in contact with the upper surfaces of the bitlines BL.

The first channel patterns AP1, the second channel patterns AP2, and the connecting channel patterns AP_CP may be distinguished based on first wordlines and second wordlines WL2.

The connecting channel patterns AP_CP may include, for example, one of IGZO, doped IZO, InO, ZnO, GaO, SnO, AZO, or ITO. In the case of the doped IZO, the doped impurities may include at least one of Mg, Sr, Ba, Sc, Y, La, Ti, Zr, Hf, Al, Sn, or Ta.

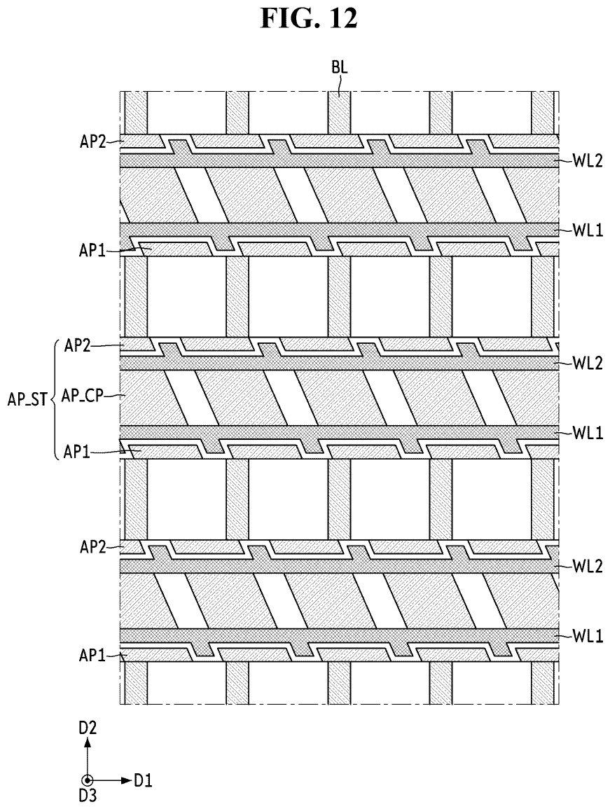

FIGS. 12, 13, 14 and 15 are diagrams for explaining semiconductor memory devices according to one or more example embodiments. For convenience of explanation, FIGS. 12, 13, 14 and 15 focus on the differences from what has been described with reference to FIGS. 1, 2, 3, 4, 5, 6, 7, 8, 9, 10 and 11.

Referring to FIG. 12, first channel patterns AP1 and second channel patterns AP2 may be alternately arranged in a diagonal direction with respect to first and second directions D1 and D2. Here, the diagonal direction may be parallel to the upper surface of a substrate 100.

Channel structures AP_ST may be formed in a twisted manner along the diagonal direction. From a planar perspective, the first channel patterns AP1, the second channel patterns AP2, and connecting channel patterns AP_CP may each have a parallelogram shape or a diamond shape.

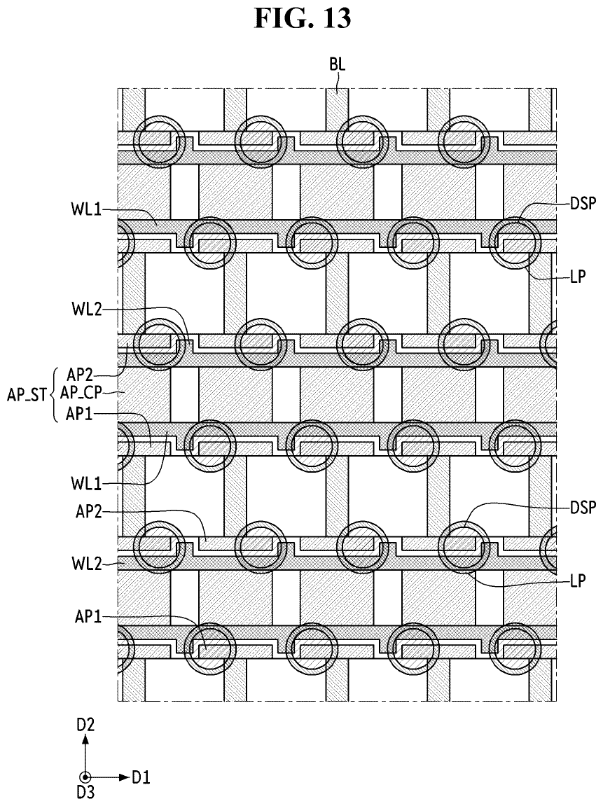

Referring to FIG. 13, landing pads LP and data storage patterns DSP may be arranged in a zigzag or honeycomb pattern from a planar perspective.

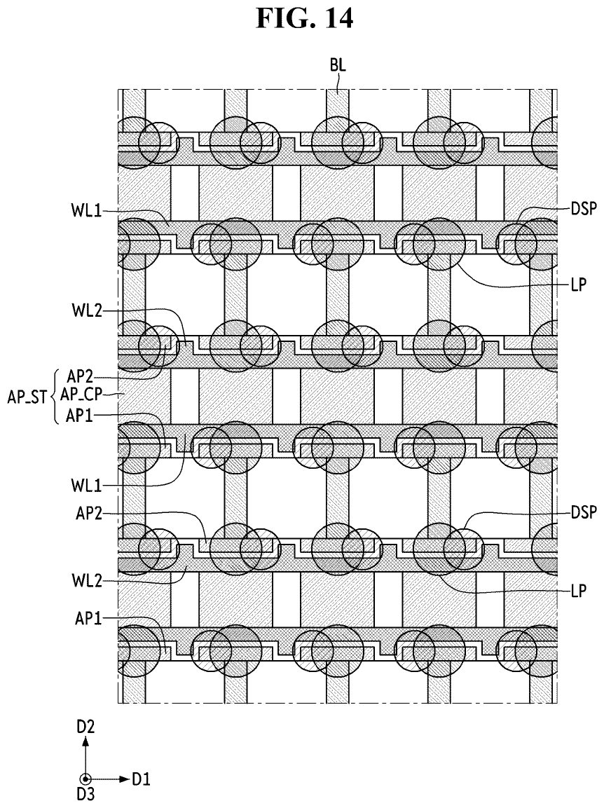

Referring to FIG. 14, data storage patterns DSP may be arranged to be offset from landing pads LP from a planar perspective.

The data storage patterns DSP may be in contact with portions of the landing pads LP.

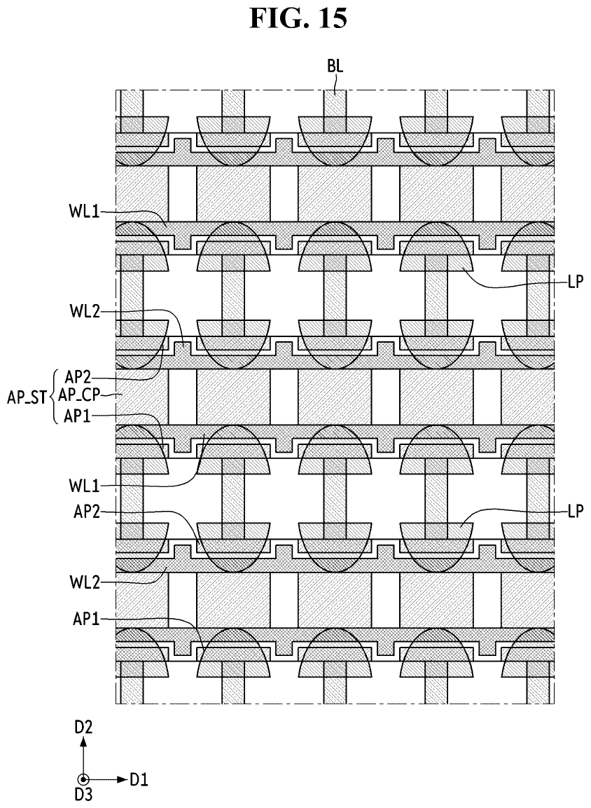

Referring to FIG. 15, landing pads LP disposed on first channel patterns AP1 or second channel patterns AP2 may have a semicircular or semi-elliptical shape from a planar perspective. The landing pads LP may be arranged symmetrically with respect to each other from a planar perspective.

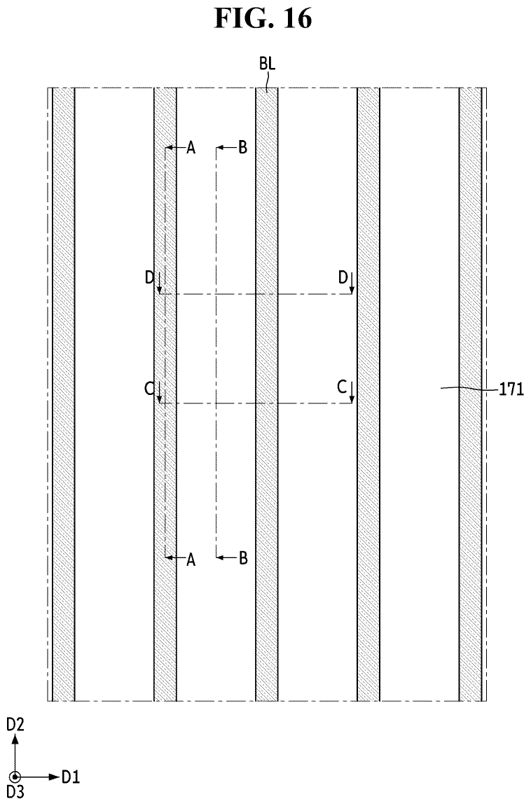

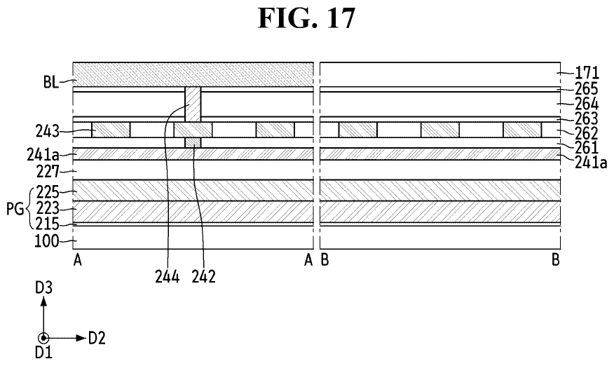

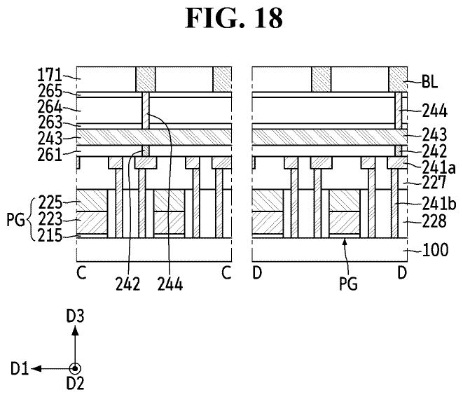

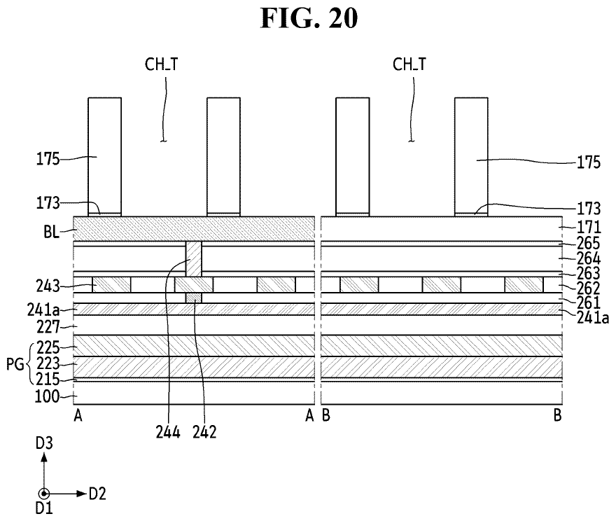

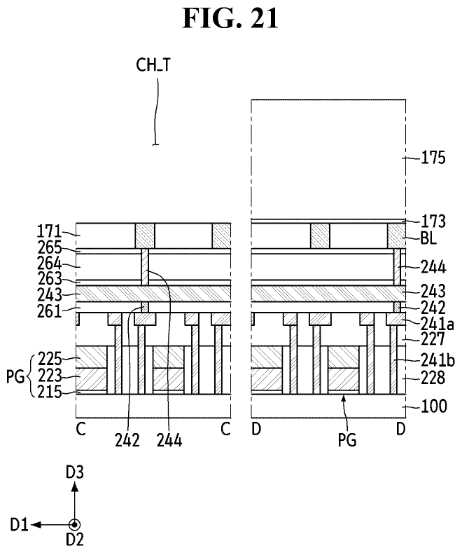

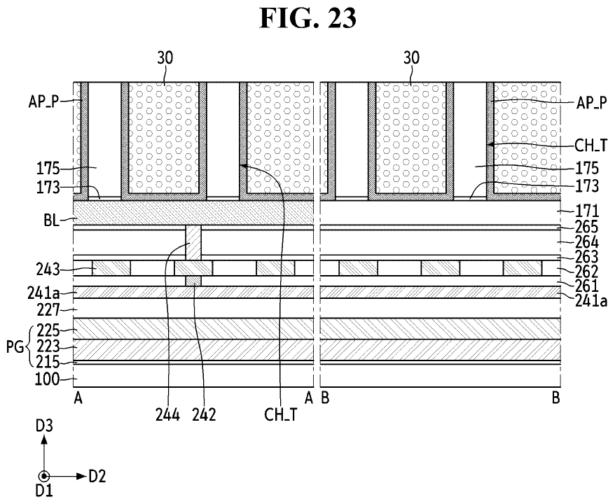

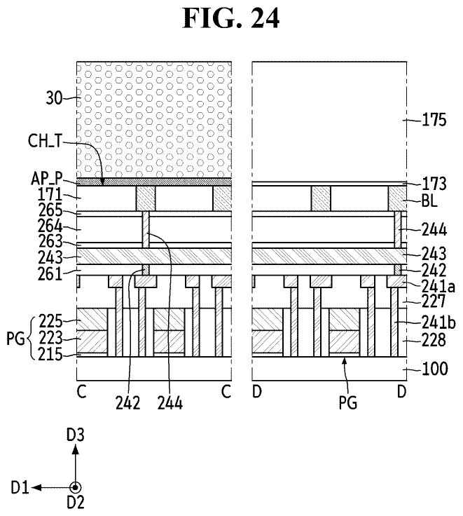

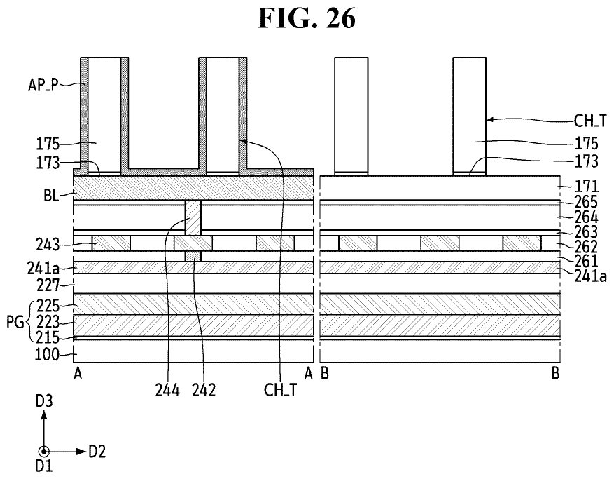

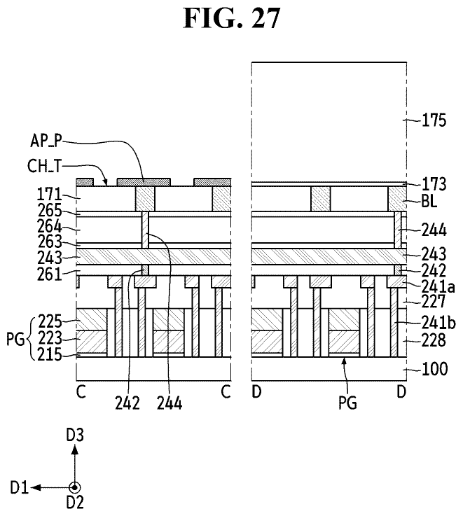

FIGS. 16, 17, 18, 19, 20, 21, 22, 23, 24, 25, 26, 27, 28, 29, 30, 31, 32, 33, 34, 35, 36, 37, 38, 39 and 40 are diagrams illustrating a method for manufacturing a semiconductor memory device according to one or more example embodiments.

Referring to FIGS. 16, 17 and 18, a peripheral gate structure PG may be formed on a substrate 100. First peripheral wiring lines 241a and peripheral contact plugs 241b may be formed on the substrate 100.

First, second, third, fourth, and fifth peripheral upper insulating films 261, 262, 263, 264, and 265 may be sequentially formed on the first peripheral wiring lines 241a and peripheral contact plugs 241b. Second peripheral wiring lines 243, peripheral via plugs 242, and cell connection plugs 244 may be formed within the first, second, third, fourth, and fifth peripheral upper insulating films 261, 262, 263, 264, and 265.

Thereafter, bitlines BL may be formed on the fifth peripheral upper insulating film 265. The bitlines BL may extend in a second direction D2 on the substrate 100. A cell lower insulating film 171 may be formed on the fifth peripheral upper insulating film 265. The cell lower insulating film 171 may expose the upper surfaces of the bitlines BL.

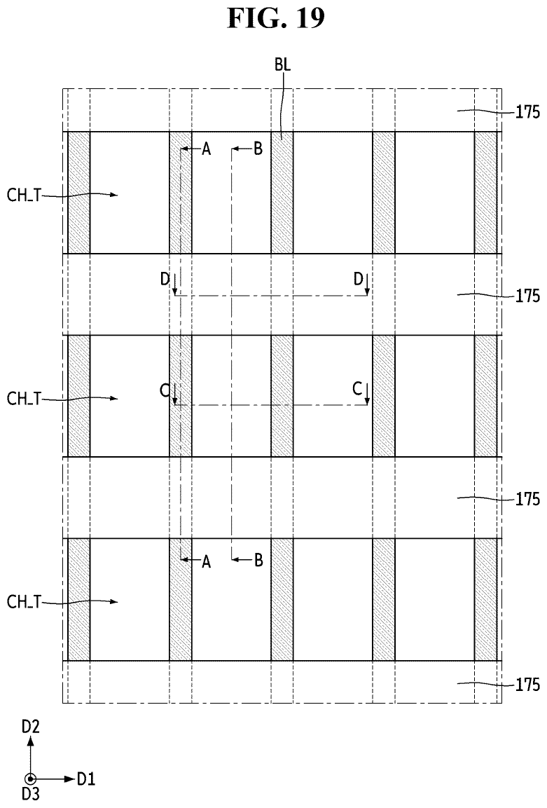

Referring to FIGS. 19, 20 and 21, protruding insulating patterns 175 may be formed on the substrate 100. Specifically, the protruding insulating patterns 175 may be formed on the bitlines BL and the cell lower insulating film 171.

A cell lower etch stop film 173 may be formed between the protruding insulating patterns 175 and the cell lower insulating film 171, but one or more example embodiments are not limited thereto.

The protruding insulating patterns 175 may include a plurality of channel trenches CH_T extending in a first direction D1. The channel trenches CH_T may intersect the bitlines BL. The channel trenches CH_T may expose the bitlines BL.

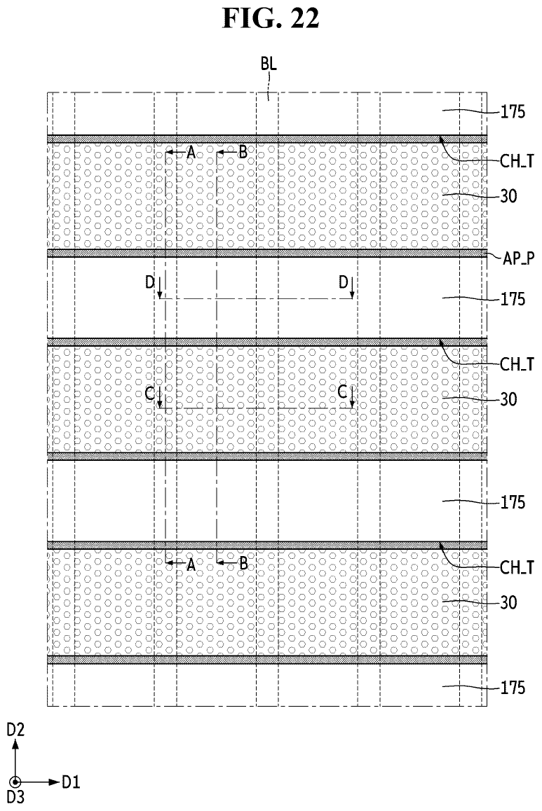

Referring to FIGS. 22, 23 and 24, preliminary channel structures AP_P may be formed on the bitlines BL and the protruding insulating patterns 175. A sacrificial film 30 may be formed on the preliminary channel structures AP_P.

Thereafter, a channel separation mask may be formed on the sacrificial film 30 and the protruding insulating patterns 175. Using the channel separation mask, portions of the sacrificial film 30 may be removed. As a result, portions of the preliminary channel structures AP_P may be exposed.

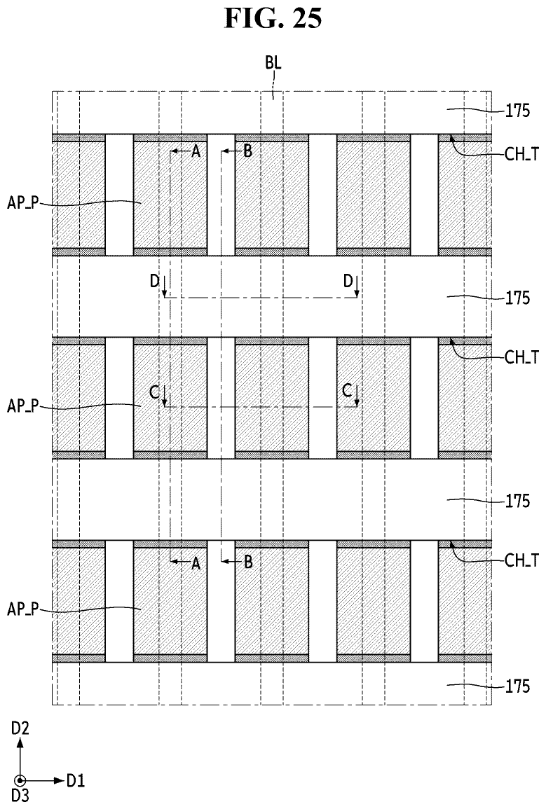

Portions of the exposed preliminary channel structures AP_P may be removed using an etching process. Thereafter, referring to FIGS. 25, 26 and 27, the sacrificial film 30 of FIGS. 22, 23 and 24 may be removed within the channel trenches CH_T.

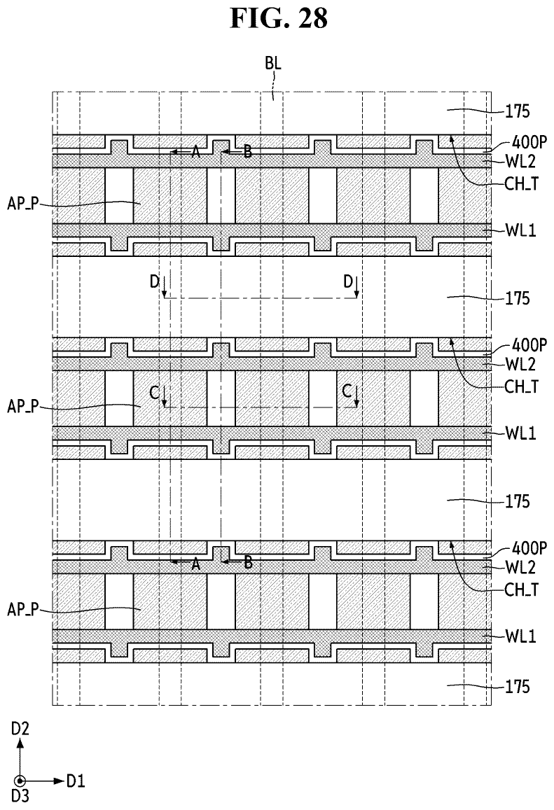

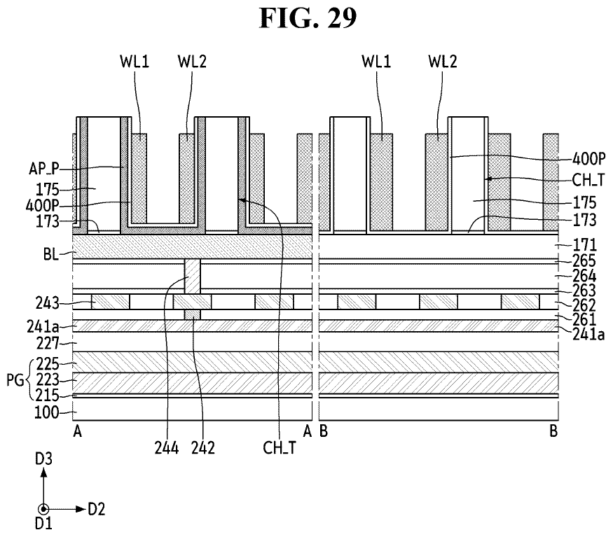

Referring to FIGS. 28 and 29, a preliminary gate insulating film 400P may be formed. The preliminary gate insulating film 400P may be formed along the profile of the preliminary channel structures AP_P. Specifically, the cross-sectional views taken along lines C-C and D-D of FIG. 28 may be the same as in the one or more example embodiments of FIG. 25.

The preliminary gate insulating film 400P may be formed using at least one of physical vapor deposition (PVD), thermal chemical vapor deposition (CVD), low-pressure chemical vapor deposition (LP-CVD), plasma-enhanced chemical vapor deposition (PE-CVD), or atomic layer deposition (ALD), but one or more example embodiments are not limited thereto.

Thereafter, first wordlines WL1 and second wordlines WL2 may be formed on the preliminary gate insulating film 400P. The first wordlines WL1 and the second wordlines WL2 may be formed along the sidewalls of the channel trenches CH_T. Forming the first wordlines WL1 and the second wordlines WL2 may involve depositing a gate conductive film on the preliminary gate insulating film 400P and performing an anisotropic etching process on the gate conductive film.

During the anisotropic etching process for the gate conductive film, portions of the preliminary gate insulating film 400P may be etched. Through this, portions of the preliminary gate insulating film 400P between the first wordlines WL1 and channel structures AP_ST may be separated from portions of the preliminary gate insulating film 400P between the second wordlines WL2 and the channel structures AP_ST. Alternatively, the preliminary gate insulating film 400P may be used as an etch stop film during the anisotropic etching process for the gate conductive film. The upper surfaces of the first wordlines WL1 and the upper surfaces of the second wordlines WL2 may be positioned at a lower level than the upper surfaces of the protruding insulating patterns 175.

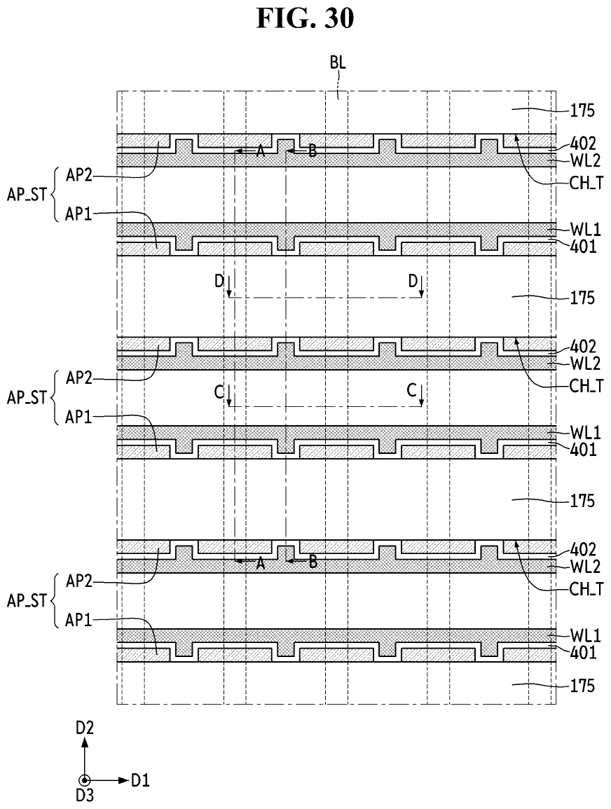

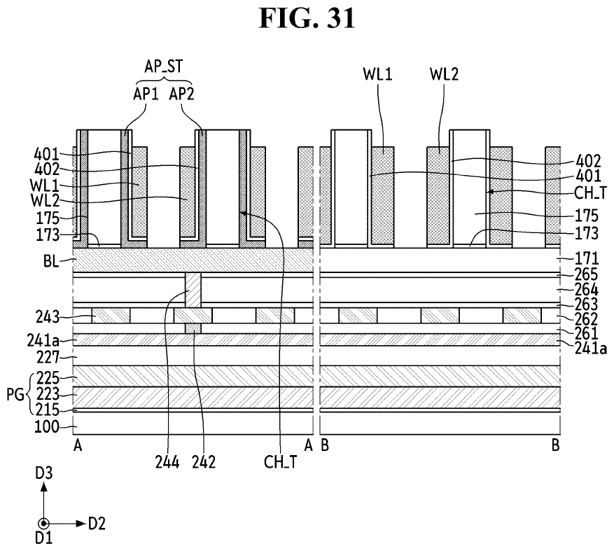

Referring to FIGS. 30 and 31, portions of the preliminary gate insulating film 400P and portions of the preliminary channel structures AP_P may be removed. For example, portions of the preliminary gate insulating film 400P and the preliminary channel structures AP_P may be removed, exposing the upper surfaces of the bitlines BL.

With the removal of portions of the preliminary gate insulating film 400P, first gate insulating patterns 401 and second gate insulating patterns 402 may be formed. The first gate insulating patterns 401 may be formed between the first wordlines WL1 and the first channel patterns AP1. The second gate insulating patterns 402 may be formed between the second wordlines WL2 and the second channel patterns AP2.

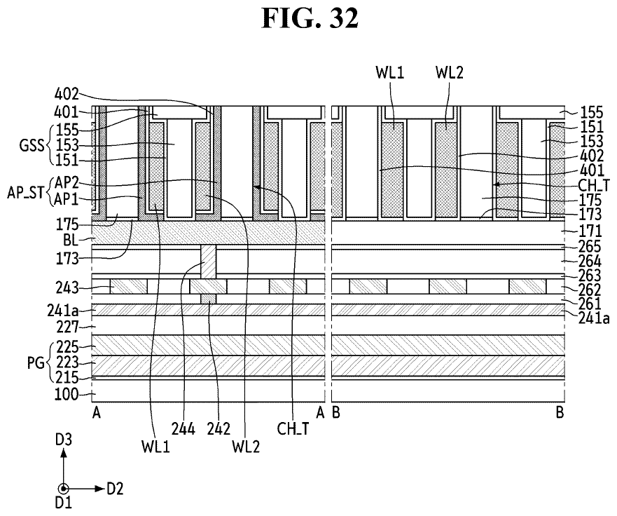

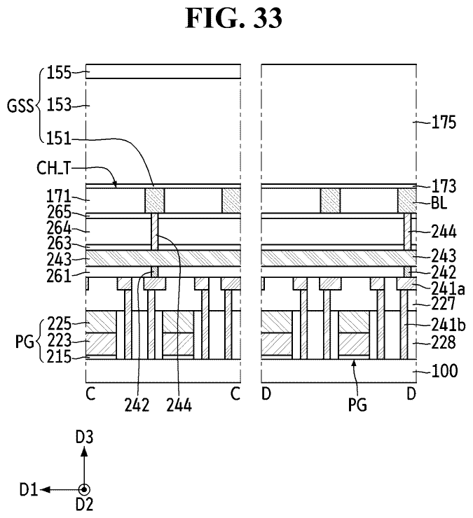

Thereafter, referring to FIGS. 32 and 33, gate separation patterns GSS may be formed on the first wordlines WL1 and the second wordlines WL2. The gate separation patterns GSS may fill the channel trenches CH_T.

Specifically, a gate separation liner 151 may be formed along the profiles of the first wordlines WL1 and the second wordlines WL2. The gate separation liner 151 may also be formed on the upper surfaces of the protruding insulating patterns 175.

A preliminary filling film may be formed on the gate separation liner 151. The preliminary filling film may also be formed on the upper surfaces of the protruding insulating patterns 175. Portions of the preliminary filling film may be removed, thereby forming a gate separation filling film 153 on the gate separation liner 151.

A preliminary capping film may be formed on the gate separation filling film 153. The preliminary capping film may also be formed on the upper surfaces of the protruding insulating patterns 175. Portions of the preliminary capping film may be removed, thereby forming a gate separation capping film 155. During the formation of the gate separation capping film 155, the gate separation liner 151 and the preliminary capping film formed on the upper surfaces of the protruding insulating patterns 175 may be removed.

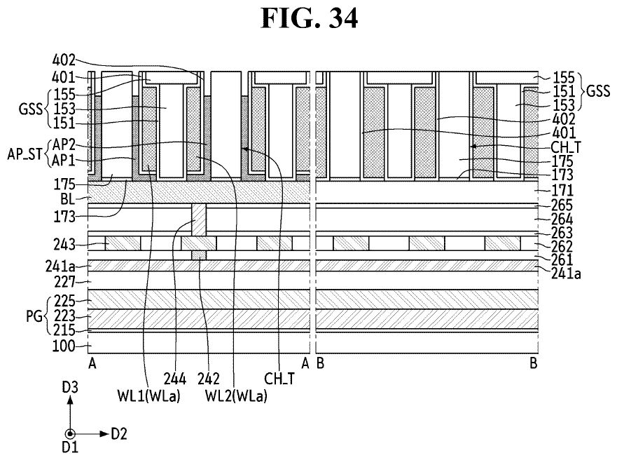

Referring to FIG. 34, at least portions of the first channel patterns AP1 and at least portions of the second channel patterns AP2 may be removed. The upper surfaces of the first channel patterns AP1 and the upper surfaces of the second channel patterns AP2 may be disposed on the same plane.

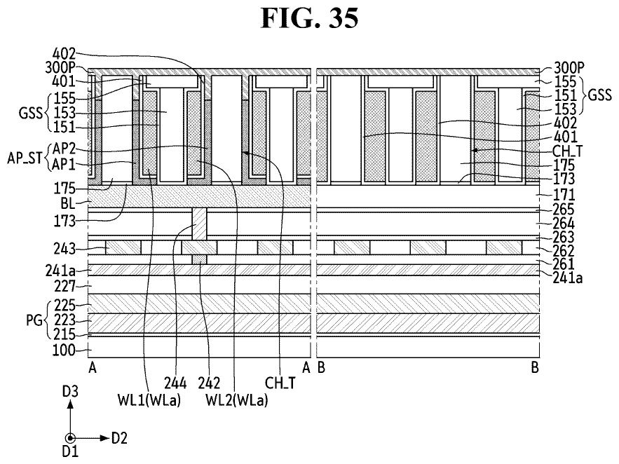

Referring to FIG. 35, a preliminary ruthenium structure 300P may be formed on the upper surfaces of the first channel patterns AP1, the upper surfaces of the second channel patterns AP2, the upper surfaces of the gate separation patterns GSS, and the upper surfaces of the protruding insulating patterns 175.

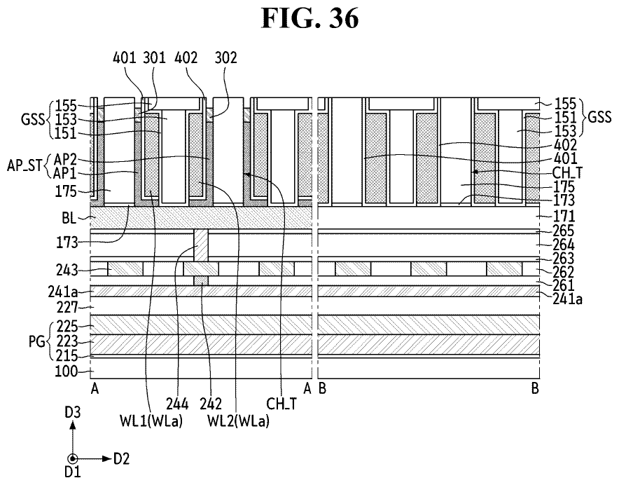

Referring to FIG. 36, portions of the preliminary ruthenium structure 300P may be removed. As a result of removing portions of the preliminary ruthenium structure 300P, a first ruthenium structure 301 and a second ruthenium structure 302 may be formed. The upper surface of the first ruthenium structure 301 may be disposed below the uppermost surfaces of the gate separation patterns GSS. Similarly, the upper surface of the second ruthenium structure 302 may be disposed below the uppermost surfaces of the gate separation patterns GSS. The upper surfaces of the first and second ruthenium structures 301 and 302 may be disposed on the same plane but are not limited thereto.

For example, at least portions of the preliminary ruthenium structure 300P may be removed using ozone gas. The ozone gas may remove the preliminary ruthenium structure 300P. Portions of the preliminary ruthenium structure 300P disposed on the upper surfaces of the channel patterns (AP1 and AP2) may remain partially intact while portions of the preliminary ruthenium structure 300P formed on the upper surfaces of the gate separation patterns GSS are removed.

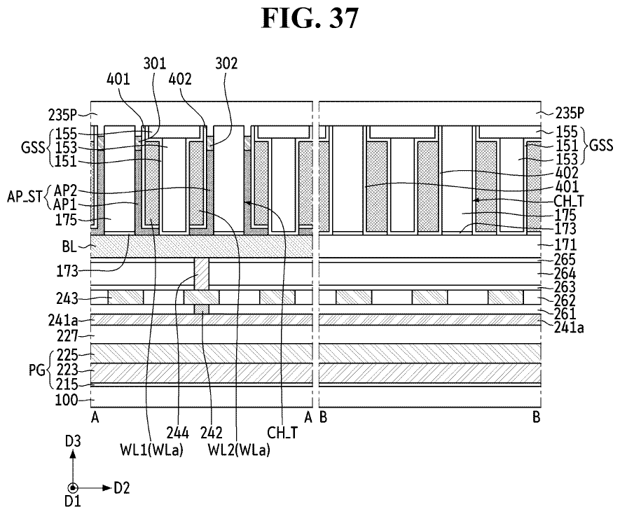

Referring to FIG. 37, preliminary pad separation insulating patterns 235P may be formed on the upper surface of the first ruthenium structure 301, the upper surface of the second ruthenium structure 302, the upper surfaces of the second gate insulating patterns 402, and the upper surfaces of the gate separation patterns GSS.

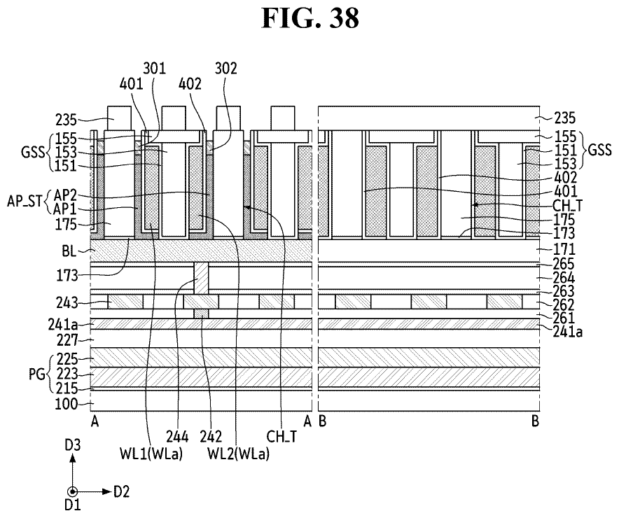

Referring to FIG. 38, portions of the preliminary pad separation insulating patterns 235P may be removed. As a result, at least portions of the upper surfaces of the gate separation patterns GSS, the upper surface of the first ruthenium structure 301, the upper surface of the second ruthenium structure 302, and the upper surfaces of the first gate insulating patterns 401, and the upper surfaces of the second gate insulating patterns 402 may be exposed.

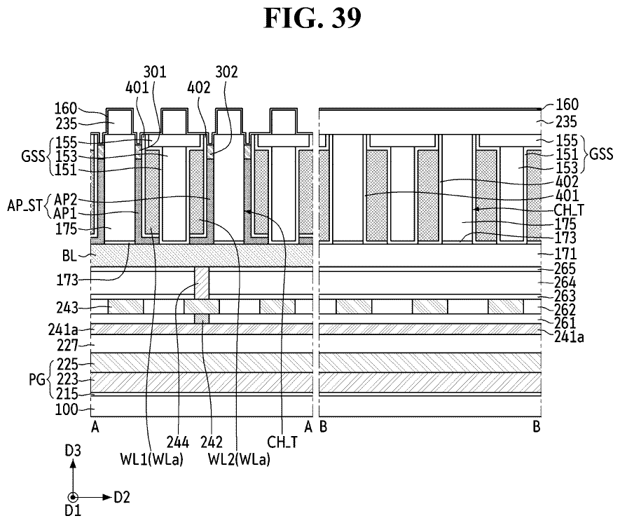

Referring to FIG. 39, a landing pad interface film 160 may be formed on the upper surfaces of the gate separation patterns GSS, the upper surface of the first ruthenium structure 301, the upper surface of the second ruthenium structure 302, the upper surfaces of the first gate insulating patterns 401, and the upper surfaces of the second gate insulating patterns 402. The landing pad interface film 160 may include, for example, TiN.

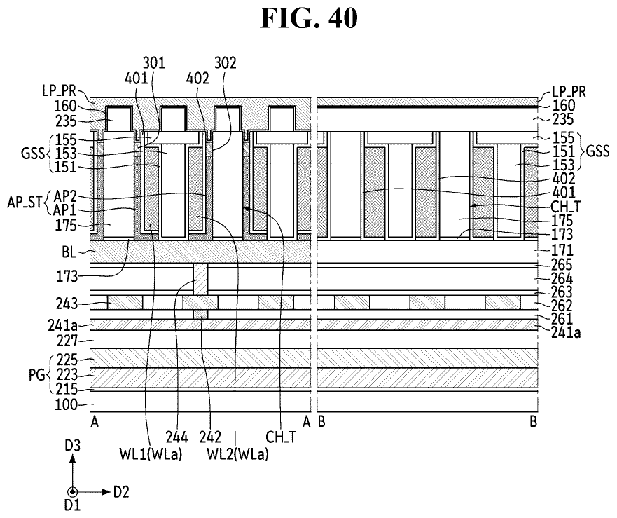

Referring to FIG. 40, a preliminary landing pad film LP_PR may be formed on the upper surface of the landing pad interface film 160. Thereafter, referring back to FIG. 2, data storage patterns DSP may be formed on landing pads LP. Specifically, the preliminary landing pad film LP_PR may be patterned, thereby forming the landing pads LP on the channel structures AP_ST.

While one or more example embodiments have been particularly shown and described above, it will be apparent to those skilled in the art that many variations and modifications in form and details may be made therein without substantially departing from the spirit and scope of one or more example embodiments of the following claims. Therefore, one or more example embodiments of the disclosure are used in a generic and descriptive sense only and not for purposes of limitation.

What is claimed is:

1. A semiconductor memory device comprising:
a substrate;
a bitline extending in a first direction on the substrate;
a first channel pattern on an upper surface of the bitline;
a second channel pattern on the upper surface of the bitline and spaced apart from the first channel pattern in the first direction, each of the first channel pattern and the second channel pattern comprising a metal oxide;
a first wordline between the first channel pattern and the second channel pattern and extending in a second direction;
a second wordline between the first channel pattern and the second channel pattern, extending in the second direction, and spaced apart from the first wordline in the first direction;
a first capacitor on the first channel pattern and connected to the first channel pattern;
a second capacitor on the second channel pattern and connected to the second channel pattern;
a first gate insulating pattern between the first channel pattern and the first wordline and extending along a profile of the first channel pattern;
a second gate insulating pattern between the second channel pattern and the second wordline and extending along a profile of the second channel pattern;
a first ruthenium structure between the first channel pattern and the first capacitor; and
a second ruthenium structure between the second channel pattern and the second capacitor,
wherein an uppermost surface of the first gate insulating pattern is provided without the first ruthenium structure thereon, and
wherein an uppermost surface of the second gate insulating pattern is provided without the second ruthenium structure thereon.

2. The semiconductor memory device of claim 1, wherein the uppermost surface of the first gate insulating pattern and an uppermost surface of the first ruthenium structure are on a same plane, and
wherein the uppermost surface of the second gate insulating pattern and an uppermost surface of the second ruthenium structure are on a same plane.

3. The semiconductor memory device of claim 1, wherein a height from a lowermost surface of the first channel pattern to the uppermost surface of the first gate insulating pattern is greater than a height from the lowermost surface of the first channel pattern to an uppermost surface of the first ruthenium structure, and
wherein a height from a lowermost surface of the second channel pattern to the uppermost surface of the second gate insulating pattern is greater than a height from the lowermost surface of the second channel pattern to an uppermost surface of the second ruthenium structure.

4. The semiconductor memory device of claim 1, wherein a height from a lowermost surface of the first channel pattern to an uppermost surface of the first ruthenium structure is greater than a height from the lowermost surface of the first channel pattern to an uppermost surface of the first wordline, and
wherein a height from a lowermost surface of the second channel pattern to an uppermost surface of the second ruthenium structure is greater than a height from the lowermost surface of the second channel pattern to an uppermost surface of the second wordline.

5. The semiconductor memory device of claim 1, wherein the first gate insulating pattern and the second gate insulating pattern do not directly contact the bitline.

6. The semiconductor memory device of claim 1, wherein the first channel pattern includes a first surface contacting the first ruthenium structure and a second surface contacting the bitline, and
wherein a width of the first surface in the first direction is less than a width of the second surface in the first direction.

7. The semiconductor memory device of claim 1, wherein the first channel pattern includes a first surface contacting the first ruthenium structure and a second surface contacting the bitline, and
wherein a width of the first surface in the first direction is the same as a width of the second surface in the first direction.

8. The semiconductor memory device of claim 1, further comprising:
a first landing pad on the first ruthenium structure;
a first landing pad interface film conformally formed along a lower surface of the first landing pad;
a second landing pad on the second ruthenium structure; and
a second landing pad interface film conformally formed along a lower surface of the second landing pad.

9. The semiconductor memory device of claim 1, wherein each of the first channel pattern and the second channel pattern includes one of: indium gallium zinc oxide (IGZO), doped indium zinc oxide (IZO), indium oxide (InO), zinc oxide (ZnO), gallium oxide (GaO), gallium oxide (GaO), aluminum zinc oxide (AZO), and indium tin oxide (ITO).

10. A semiconductor memory device comprising:
a substrate;
a bitline extending in a first direction on the substrate;
a channel pattern on an upper surface of the bitline and comprising a metal oxide;
a wordline extending in a second direction on the channel pattern;
a gate insulating pattern between the channel pattern and the wordline;
a landing pad on the channel pattern; and
a ruthenium structure between the channel pattern and the landing pad and connecting the channel pattern and the landing pad,
wherein the channel pattern comprises a horizontal part contacting the bitline and a vertical part extending in a third direction from the horizontal part, and
wherein an uppermost surface of the gate insulating pattern is provided without the ruthenium structure thereon.

11. The semiconductor memory device of claim 10, wherein the uppermost surface of the gate insulating pattern and an uppermost surface of the ruthenium structure are on a same plane.

12. The semiconductor memory device of claim 10, wherein a height from a lowermost surface of the channel pattern to the uppermost surface of the gate insulating pattern is greater than a height from the lowermost surface of the channel pattern to an uppermost surface of the ruthenium structure.

13. The semiconductor memory device of claim 10, wherein a height from a lowermost surface of the channel pattern to an uppermost surface of the ruthenium structure is greater than a height from the lowermost surface of the channel pattern to an uppermost surface of the wordline.

14. The semiconductor memory device of claim 10, wherein a width of the horizontal part of the channel pattern in the first direction is greater than a width of the vertical part of the channel pattern in the first direction.

15. The semiconductor memory device of claim 10, wherein a width of the ruthenium structure in the first direction is the same as a width of the vertical part of the channel pattern in the first direction.

16. The semiconductor memory device of claim 10, wherein a width of the horizontal part of the channel pattern in the first direction is greater than a width of the ruthenium structure in the first direction.

17. The semiconductor memory device of claim 10, wherein the channel pattern includes one of: indium gallium zinc oxide (IGZO), doped indium zinc oxide (IZO), indium oxide (InO), zinc oxide (ZnO), gallium oxide (GaO), gallium oxide (GaO), aluminum zinc oxide (AZO), and indium tin oxide (ITO).

18. A semiconductor memory device comprising:
a substrate;
a peripheral gate structure on the substrate;
a bitline extending in a first direction on the peripheral gate structure;
a channel pattern on an upper surface of the bitline and comprising a metal oxide;
a wordline on the channel pattern and extending in a second direction;
a gate insulating pattern between the channel pattern and the wordline;
a landing pad on the channel pattern and connected to the channel pattern;
a ruthenium structure between the channel pattern and the landing pad; and
a data storage pattern on the landing pad,
wherein the channel pattern includes a horizontal part contacting the bitline and a vertical part extending in a third direction from the horizontal part, and
wherein an uppermost surface of the gate insulating pattern is provided without the ruthenium structure thereon.

19. The semiconductor memory device of claim 18, wherein the uppermost surface of the gate insulating pattern and an uppermost surface of the ruthenium structure are on a same plane.

20. The semiconductor memory device of claim 18, wherein a height from a lowermost surface of the channel pattern to the uppermost surface of the gate insulating pattern is greater than a height from the lowermost surface of the channel pattern to an uppermost surface of the ruthenium structure.
